(19) United States
(12) Patent Application Publication
(10) Pub. No.: US 2026/0260620 A1
(43) Pub. Date: Sep. 3, 2026

(54) SHIFT REGISTER UNIT AND DRIVING METHOD THEREOF, GATE DRIVING CIRCUIT AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Xu LU, Beijing (CN); Li XIAO, Beijing (CN); Zijian WANG, Beijing (CN)

(21) Appl. No.: 18/869,543

(22) PCT Filed: Aug. 12, 2024
(86) PCT No.: PCT/CN2024/111527

§ 371 Date: Nov. 26, 2024

(30) Foreign Application Priority Data
Sep. 11, 2023 (CN) 202311167558.4

(51) Int. Cl. G09G 3/3266; G11C 19/28

(52) U.S. Cl. CPC G09G 3/3266; G11C 19/28; G09G 2300/0408; G09G 2310/0286

(57) ABSTRACT

A shift register unit and a driving method thereof, a gate driving circuit and a display apparatus are provided. A pre-stage driving circuit controls a connection between a first power supply terminal or a second power supply terminal and a pre-stage output terminal to be switched on and transmit a pre-stage signal to the pre-stage output terminal. A post-stage control circuit controls a connection between the pre-stage output terminal or an output control terminal and a post-stage output terminal connected to pixels to be switched on based on the pre-stage signal and an output control signal provided by the output control terminal, and when a connection between the output control terminal and the post-stage output terminal is controlled to be switched on, the potential of the transmitted output control signal is not less than the potential of a first power supply signal provided by the first power supply terminal.

### CROSS-REFERENCE TO RELATED APPLICATION

The present disclosure is a national stage of PCT application No. PCT/CN2024/111527, filed on Aug. 12, 2024, which claims priority to Chinese Patent Application No. 202311167558.4, filed on Sep. 11, 2023 and entitled “SHIFT REGISTER UNIT AND DRIVING METHOD THEREOF, GATE DRIVING CIRCUIT AND DISPLAY APPARATUS”, the entire contents of both of which are incorporated herein by reference.

### TECHNICAL FIELD

The present disclosure relates to the field of display technologies, in particular to a shift register unit and a driving method thereof, a gate driving circuit and a display apparatus.

### BACKGROUND

The gate driving circuit is one of essential circuits for driving displaying of a display panel, and is currently mostly integrated into a display substrate by a gate drive on array (GOA) technology to facilitate a narrow bezel design. Correspondingly, the gate driving circuit is also called a GOA circuit.

In related art, the GOA circuit generally includes a plurality of cascaded GOA units, and each GOA unit may be called a shift register unit. The plurality of GOA units are connected to multiple rows of pixels in the display panel through output terminals, and are configured to output gate driving signals to the multiple rows of pixels row by row, thereby realizing row scanning driving to light the multiple rows of pixels row by row, and enabling the display panel to display pictures. Moreover, each GOA unit generally includes a plurality of P-type transistors, and the pixels generally include a plurality of N-type transistors.

However, based on the principle that the N-type transistors are turned on at high potential, it is known that each GOA unit needs to output a low-potential gate driving signal for a long time. As a result, the risk of characteristic deviation of the transistors in the GOA unit will be caused, and output stability of the GOA unit is poor, which further easily leads to abnormal display of the display panel.

### SUMMARY

Provided are a shift register unit and a driving method thereof, a gate driving circuit and a display apparatus. The technical solution is as follows.

In one aspect, a shift register unit is provided. The shift register unit includes:
a pre-stage driving circuit respectively connected to a driving control terminal, a first power supply terminal, a second power supply terminal and a pre-stage output terminal, and configured to control switching on and off of a connection between the first power supply terminal and the pre-stage output terminal and switching on and off of a connection between the second power supply terminal and the pre-stage output terminal based on a driving control signal provided by the driving control terminal; and
a post-stage control circuit respectively connected to the pre-stage output terminal, an output control terminal and a post-stage output terminal, wherein the post-stage output terminal is configured to be connected to pixels in a display panel, and the post-stage control circuit is configured to control a connection between the pre-stage output terminal and the post-stage output terminal to be switched on based on a pre-stage signal from the pre-stage output terminal and an output control signal provided by the output control terminal, so that the pre-stage signal is transmitted from the pre-stage output terminal to the post-stage output terminal, or, control a connection between the output control terminal and the post-stage output terminal to be switched on, so that the output control signal is transmitted from the output control terminal to the post-stage output terminal, and a potential of the transmitted output control signal is not less than a potential of a first power supply signal provided by the first power supply terminal.

Optionally, a switch-on duration of the connection between the first power supply terminal and the pre-stage output terminal is less than a switch-on duration of the connection between the second power supply terminal and the pre-stage output terminal; the output control terminal includes a first output control terminal and a second output control terminal, wherein a potential of an output control signal provided by the second output control terminal is not less than the potential of the first power supply signal;
the post-stage control circuit is configured to control switching on and off of a connection between the pre-stage output terminal and the post-stage output terminal based on the pre-stage signal and an output control signal provided by the first output control terminal, and control a connection between the second output control terminal and the post-stage output terminal to be switched on upon controlling the connection between the pre-stage output terminal and the post-stage output terminal to be switched off.

Optionally, the post-stage control circuit includes:
a switching sub-circuit respectively connected to the first output control terminal, the pre-stage output terminal and the post-stage output terminal, and configured to control the switching on and off of the connection between the pre-stage output terminal and the post-stage output terminal based on the pre-stage signal and the output control signal provided by the first output control terminal; and
an isolation sub-circuit respectively connected to the second output control terminal and the post-stage output terminal, and configured to isolate the second output control terminal from the post-stage output terminal, and control a connection between the second output control terminal and the post-stage output terminal to be switched on when the switching sub-circuit controls the connection between the pre-stage output terminal and the post-stage output terminal to be switched off.

Optionally, the switching sub-circuit includes a switch and a first resistor;
a control terminal of the switch is connected to the first output control terminal, an input terminal of the switch is connected to the pre-stage output terminal, and an output terminal of the switch is connected to the post-stage output terminal; and
one terminal of the first resistor is connected to the pre-stage output terminal, and the other terminal of the first resistor is connected to the first output control terminal.

Optionally, the switch includes: a switching transistor;
wherein a gate electrode of the switching transistor is connected to the first output control terminal as the control terminal of the switch, a first electrode of the switching transistor is connected to the pre-stage output terminal as the input terminal of the switch, and a second electrode of the switching transistor is connected to the post-stage output terminal as the output terminal of the switch.

Optionally, the isolation sub-circuit includes: a second resistor; and
one terminal of the second resistor is connected to the second output control terminal, and the other terminal of the second resistor is connected to the post-stage output terminal.

Optionally, the driving control terminal includes a first clock terminal, a second clock terminal, a start signal terminal and a potential control terminal;
the pre-stage driving circuit is configured to control the switching on and off of the connection between the first power supply terminal and the pre-stage output terminal and the switching on and off of the connection between the second power supply terminal and the pre-stage output terminal based on a first clock signal provided by the first clock terminal, a second clock signal provided by the second clock terminal, a start signal provided by the start signal terminal, a potential control signal provided by the potential control terminal, the first power supply signal and a second power supply signal provided by the second power supply terminal.

Optionally, the pre-stage driving circuit includes a first transistor, a second transistor, a third transistor, a fourth transistor, a fifth transistor, a sixth transistor, a seventh transistor, an eighth transistor, a ninth transistor, a tenth transistor, an eleventh transistor, a twelfth transistor, a thirteenth transistor, a fourteenth transistor, a fifteenth transistor, a sixteenth transistor, a first capacitor, a second capacitor and a third capacitor;
wherein a gate electrode of the first transistor is connected to the first clock terminal, a first electrode of the first transistor is connected to the start signal terminal, and a second electrode of the first transistor is connected to a first node;
a gate electrode of the second transistor is connected to the first node, a first electrode of the second transistor is connected to the first clock terminal, and the first electrode of the second transistor is connected to a second node;
a gate electrode of the third transistor is connected to the first clock terminal, a first electrode of the third transistor is connected to the second power supply terminal, and a second electrode of the third transistor is connected to the second node;
a gate electrode of the fourth transistor is connected to a tenth node, a first electrode of the fourth transistor is connected to the second clock terminal, and a second electrode of the third transistor is connected to a fifth node;
a gate electrode of the fifth transistor is connected to the second node, a first electrode of the fifth transistor is connected to the first power supply terminal, and a second electrode of the fifth transistor is connected to the fifth node;
a gate electrode of the sixth transistor is connected to a sixth node, a first electrode of the sixth transistor is connected to the second clock terminal, and a second electrode of the sixth transistor is connected to a third node;
a gate electrode of the seventh transistor is connected to the second clock terminal, a first electrode of the seventh transistor is connected to the third node, and a second electrode of the seventh transistor is connected to a fourth node;
a gate electrode of the eighth transistor is connected to the first node, a first electrode of the eighth transistor is connected to the first power supply terminal, and a second electrode of the eighth transistor is connected to the fourth node;
a gate electrode of the ninth transistor is connected to the fourth node, a first electrode of the ninth transistor is connected to the first power supply terminal, and a second electrode of the ninth transistor is connected to the pre-stage output terminal;
a gate electrode of the tenth transistor is connected to a seventh node, a first electrode of the tenth transistor is connected to the second power supply terminal, and a second electrode of the tenth transistor is connected to the pre-stage output terminal;
a gate electrode of the eleventh transistor is connected to the second power supply terminal, a first electrode of the eleventh transistor is connected to the second node, and a second electrode of the eleventh transistor is connected to the sixth node;
a gate electrode of the twelfth transistor is connected to the second power supply terminal, a first electrode of the twelfth transistor is connected to the first node, and a second electrode of the twelfth transistor is connected to the seventh node;
a gate electrode of the thirteenth transistor is connected to the potential control terminal, a first electrode of the thirteenth transistor is connected to the first power supply terminal, and a second electrode of the thirteenth transistor is connected to the first node;
a gate electrode of the fourteenth transistor is connected to the first clock terminal, a first electrode of the fourteenth transistor is connected to the start signal terminal, and a second electrode of the fourteenth transistor is connected to an eighth node;
a gate electrode of the fifteenth transistor is connected to the second power supply terminal, a first electrode of the fifteenth transistor is connected to the eighth node, and a second electrode of the fifteenth transistor is connected to a ninth node;
a gate electrode and a first electrode of the sixteenth transistor are both connected to the ninth node, and a second electrode of the sixteenth transistor is connected to the seventh node;
one terminal of the first capacitor is connected to the sixth node, and the other terminal of the first capacitor is connected to the third node; one terminal of the second capacitor is connected to the fourth node, and the other terminal of the second capacitor is connected to the first power supply terminal; and one terminal of the third capacitor is connected to the fifth node, and the other terminal of the third capacitor is connected to the ninth node.

Optionally, transistors in the pre-stage driving circuit are P-type transistors, and a material of the P-type transistor includes low temperature poly-silicon;
wherein the potential of the first power supply signal provided by the first power supply terminal is greater than a potential of the second power supply signal provided by the second power supply terminal.

In another aspect, a driving method of a shift register unit is provided and applied to the shift register unit according to the above aspect. The method includes:
controlling, by the pre-stage driving circuit, a connection between the first power supply terminal and the pre-stage output terminal and a connection between the second power supply terminal and the pre-stage output terminal to be switched on in turn based on the driving control signal provided by the driving control terminal;
if a potential of the pre-stage signal from the pre-stage output terminal is less than a potential threshold, controlling, by the post-stage control circuit, a connection between the pre-stage output terminal and the post-stage output terminal to be switched on based on the pre-stage signal and the output control signal provided by the output control terminal, so that the pre-stage signal is transmitted from the pre-stage output terminal to the post-stage output terminal;
if the potential of the pre-stage signal is greater than the potential threshold, controlling, by the post-stage control circuit, a connection between the output control terminal and the post-stage output terminal to be switched on based on the pre-stage signal and the output control signal provided by the output control terminal, so that the output control signal is transmitted from the output control terminal to the post-stage output terminal, and the potential of the transmitted output control signal is not less than the potential of the first power supply signal;
wherein the potential threshold is between the potential of the first power supply signal and the potential of the second power supply signal provided by the second power supply terminal.

Optionally, the pre-stage driving circuit controls the switch-on duration of the connection between the first power supply terminal and the pre-stage output terminal to be less than the switch-on duration of the connection between the second power supply terminal and the pre-stage output terminal;
the output control terminal includes the first output control terminal and the second output control terminal, wherein the potential of the output control signal provided by the second output control terminal is not less than the potential of the first power supply signal;
controlling, by the post-stage control circuit, a connection between the pre-stage output terminal and the post-stage output terminal to be switched on based on the pre-stage signal and the output control signal provided by the output control terminal includes:
controlling, by the post-stage control circuit, a connection between the pre-stage output terminal and the post-stage output terminal to be switched on based on the pre-stage signal and the output control signal provided by the first output control terminal;
controlling, by the post-stage control circuit, a connection between the output control terminal and the post-stage output terminal to be switched on based on the pre-stage signal and the output control signal provided by the output control terminal includes:
controlling, by the post-stage control circuit, the connection between the pre-stage output terminal and the post-stage output terminal to be switched off based on the pre-stage signal and the output control signal provided by the first output control terminal, so that a connection between the second output control terminal and the post-stage output terminal is switched on.

Optionally, a potential of the output control signal provided by the first output control terminal is positively correlated to the potential threshold.

In yet another aspect, a gate driving circuit is provided. The gate driving circuit includes at least two cascaded shift register units according to the above one aspect.

In still a further aspect, a display apparatus is provided. The display apparatus includes: a display panel, and the gate driving circuit according to the above yet another aspect;
wherein the display panel includes a plurality of pixels, and the gate driving circuit is connected to the plurality of pixels and configured to transmit gate driving signals to the plurality of pixels to drive the plurality of pixels to emit light.

Optionally, transistors in the pixels are N-type transistors, and a material of the N-type transistor includes an oxide material.

### BRIEF DESCRIPTION OF DRAWINGS

To describe the technical solutions in the embodiments of the present disclosure more clearly, the following briefly introduces the accompanying drawings required for describing the embodiments. Apparently, the accompanying drawings in the following description show merely some embodiments of the present disclosure, and a person of ordinary skill in the art may still derive other drawings from these accompanying drawings without creative efforts.

FIG. 1 is a schematic structural diagram of a shift register unit according to an embodiment of the present disclosure;

FIG. 2 is a waveform diagram of output signals of a shift register unit in the related art;

FIG. 3 is a waveform diagram of output signals of a shift register unit according to an embodiment of the present disclosure;

FIG. 4 is a schematic structural diagram of another shift register unit according to an embodiment of the present disclosure;

FIG. 5 is a schematic structural diagram of yet another shift register unit according to an embodiment of the present disclosure;

FIG. 6 is a circuit schematic structural diagram of a shift register unit according to an embodiment of the present disclosure;

FIG. 7 is a flowchart of a driving method of a shift register unit according to an embodiment of the present disclosure;

FIG. 8 is a schematic structural diagram of a gate driving circuit according to an embodiment of the present disclosure; and

FIG. 9 is a structural schematic diagram of a display apparatus according to an embodiment of the present disclosure.

### DETAILED DESCRIPTION

For clear descriptions of the objects, technical solutions and advantages in the present disclosure, the embodiments of the present disclosure are described in further detail below in combination with the accompanying drawings.

It should be noted that transistors used in all the embodiments of the present disclosure may be thin film transistors or field-effect transistors or other devices with the same characteristics. The transistors used in the embodiments of the present disclosure are mainly switching transistors according to the functions in the circuit. Since a source electrode and a drain electrode of the switching transistor used here are symmetrical, the source electrode and the drain electrode are interchangeable. In the embodiments of the present disclosure, the source electrode is referred to as a first electrode and the drain electrode is referred to as a second electrode. According to the form in the drawings, an intermediate terminal of the transistor is a control electrode, which may also be referred to as a gate electrode, a signal input terminal is the source electrode, and a signal output terminal is the drain electrode. In addition, the switching transistors used in the embodiments of the present disclosure may include any one of a P-type transistor and an N-type transistor. The P-type transistor is turned on when the gate electrode is at a low voltage and is turned off when the gate electrode is at a high voltage, and the N-type transistor is turned on when the gate electrode is at a high voltage and turned off when the gate electrode is at a low voltage. In addition, a plurality of signals in various embodiments of the present disclosure each correspond to a first potential and a second potential. The first potential and the second potential only represent that the signal has potentials with two different state quantities, and do not represent that the first potential or the second potential has a specific value.

At present, common display panels include: organic light-emitting diode (OLED) display panels having the advantages such as self-luminescence, fast response speed and low energy consumption. In the field of OLED display, a GOA circuit including the P-type transistors and pixels including the N-type transistors are often adopted to realize high-precision frequency conversion display driving. A material of the P-type transistor generally includes a low temperature poly-silicon (LTPS) material, and a material of the N-type transistor generally includes an oxide material, which are also correspondingly called an LTPO architecture. The material of the transistor refers to the material of an active layer included in the transistor.

However, through testing, it is found that under the OLED LTPO architecture, since each GOA unit in the GOA circuit needs to output a low-potential driving signal for a long time, the transistors in the GOA unit are prone to the problem of negative characteristic shift, the output driving signal easily generates a VX platform (VX refers to the intermediate potential between a normal high potential and a normal low potential of the driving signal), and the output stability is relatively poor, which further generates a reliability problem. After accelerated deterioration of the reliability problem, the phenomenon of poor transverse striations of the OLED display panel will be caused.

The embodiments of the present disclosure optimize the design of the current GOA unit, and the VX platform does not exist in the driving signal output by the optimized GOA unit, that is, the VX platform can be removed by optimization, so as to eliminate the poor transverse striations caused by a charging difference between different rows of pixels due to an unstable output difference, that is, different pixels can be reliably driven to emit light normally, so that the display effect of the display panel can be better.

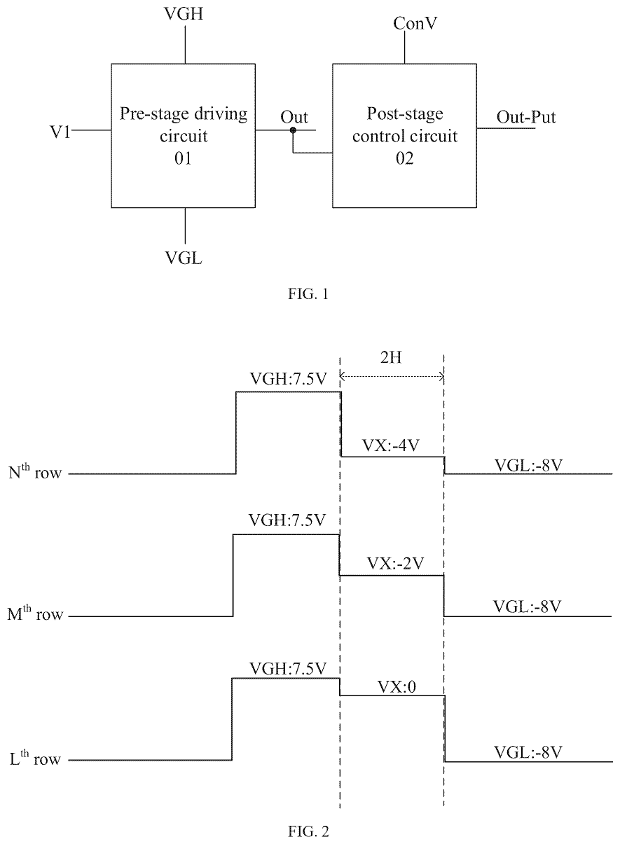

FIG. 1 is a schematic structural diagram of a shift register unit according to an embodiment of the present disclosure. As shown in FIG. 1, the shift register unit includes a pre-stage driving circuit 01 and a post-stage control circuit 02.

The pre-stage driving circuit 01 is respectively connected to a driving control terminal V1, a first power supply terminal VGH, a second power supply terminal VGL and a pre-stage output terminal Out, and is configured to control the switching on and off of the connection between the first power supply terminal VGH and the pre-stage output terminal Out and the switching on and off of the connection between the second power supply terminal VGL and the pre-stage output terminal Out based on a driving control signal provided by the driving control terminal V1.

Exemplarily, under the control of the driving control signal provided by the driving control terminal V1, the pre-stage driving circuit 01 may control the connection between the first power supply terminal VGH and the pre-stage output terminal Out to be switched on, so that a first power supply signal provided by the first power supply terminal VGH can be transmitted to the pre-stage output terminal Out, and at this time, the second power supply terminal VGL is also controlled to be decoupled from the pre-stage output terminal Out. In addition, the pre-stage driving circuit 01 may control the connection between the second power supply terminal VGL and the pre-stage output terminal Out to be switched on under the control of the driving control signal, so that a second power supply signal provided by the second power supply terminal VGL can be transmitted to the pre-stage output terminal Out, and at this time, the first power supply terminal VGH is also controlled to be decoupled from the pre-stage output terminal Out. That is, at the same time period, the pre-stage driving circuit 01 may control the connection between the first power supply terminal VGH or the second power supply terminal VGL and the pre-stage output terminal Out to be switched on to output the first power supply signal or the second power supply signal to the pre-stage output terminal Out.

Moreover, a switch-on duration of the connection between the first power supply terminal VGH and the pre-stage output terminal Out may be less than a connection duration that between the second power supply terminal VGL and the pre-stage output terminal Out. That is, the pre-stage driving circuit 01 may output the second power supply signal to the pre-stage output terminal Out for a long time. In other words, a potential of the first power supply signal may be regarded as an effective potential output to the pre-stage output terminal Out, and a potential of the second power supply signal may be regarded as an ineffective potential output to the pre-stage output terminal Out. Driven by the effective potential, the pixels may be driven to emit light.

Optionally, the potential of the first power supply signal may be a high potential, and the potential of the second power supply signal may be a low potential. The high potential and the low potential are relative. Of course, in some other embodiments, the potential of the first power supply signal may also be a low potential, and the potential of the second power supply signal may also be a high potential.

With continued reference to FIG. 1, the post-stage control circuit 02 is respectively connected to the pre-stage output terminal Out, an output control terminal ConV and a post-stage output terminal Out-Put, and the post-stage output terminal Out-Put is configured to be connected to the pixels 9 (not shown) in the display panel. The post-stage control circuit 02 is configured to control the connection between the pre-stage output terminal Out and the post-stage output terminal Out-Put to be switched on based on a pre-stage signal from the pre-stage output terminal Out and an output control signal provided by the output control terminal ConV, so that the pre-stage output terminal OUT transmits the pre-stage signal to the post-stage output terminal Out-Put, or control the connection between the output control terminal ConV and the post-stage output terminal Out-Put to be switched on, so that the output control terminal ConV transmits the output control signal to the post-stage output terminal Out-Put, and a potential of the output control signal transmitted to the post-stage output terminal Out-Put is not less than (i.e., greater than or equal to) the potential of the first power supply signal provided by the first power supply terminal VGH.

In the related art, the shift register unit directly sets the pre-stage driving circuit 01 to be connected to the pixels through the pre-stage output terminal Out, so as to transmit the driving signals to the pixels and drive the pixels to emit light, that is, the post-stage control circuit 02 is not disposed. Based on such an arrangement, due to an impact of the negative characteristic shift caused by long-term output of the low potential, the driving signals transmitted to the pixels often show the VX platforms as shown in FIG. 2. That is, assuming that the potential of the first power supply signal is 7.5 volts (V) and the potential of the second power supply signal is −8V, then an intermediate potential VX between 7.5V and −8V is prone to appear, and a duration of the intermediate potential VX is more than or equal to 2H. Moreover, the sizes of VXs are different for different rows of pixels. For example, referring to FIG. 2, which schematically shows three rows of pixels in the N^{th}, M^{th} and L^{th} rows. When the pixels in the N^{th}, M^{th} and L^{th} rows are driven to emit light, the VXs of the driving signals transmitted to the pixels are −4V, −2V and 0 respectively. Therefore, the abnormal display problem of poor transverse striations as described in the above embodiment is easily caused. N, M and L are different integers greater than or equal to 1.

Based on this, in the embodiment of the present disclosure, one post-stage control circuit 02 is additionally disposed between the pre-stage output terminal Out and the pixels, so that the pre-stage driving circuit 01 is indirectly connected to the pixels through the post-stage control circuit 02, that is, the pre-stage output terminal Out is not directly disposed to be connected to the pixels, but the post-stage control circuit 02 is disposed to indirectly couple the pre-stage output terminal Out with the pixels through the post-stage output terminal Out-Put. Based on this, combined with a working principle of the post-stage control circuit 02, it can be known that the embodiment of the present disclosure can eliminate the VX platforms in the following way to solve the abnormal display problem of poor transverse striations. Exemplarily, the post-stage control circuit 02 is configured as:

If the potential of the pre-stage signal from the pre-stage output terminal Out is less than a potential threshold, then the connection between pre-stage output terminal Out and the post-stage output terminal Out-Put is controlled to be switched on, so that the pre-stage output terminal Out directly transmits the pre-stage signal to the pixels connected to the post-stage output terminal Out-Put to drive the pixels to emit light. That is, the driving signal transmitted to the pixels is the pre-stage signal. Here, it may also be considered as synchronizing the pre-stage signal from the pre-stage output terminal Out to the post-stage output terminal Out-Put.

If the potential of the pre-stage signal from the pre-stage output terminal Out is greater than the potential threshold, then the connection between the output control terminal ConV and the post-stage output terminal Out-Put is controlled to be switched on, so that the output control terminal ConV, instead of the pre-stage output terminal Out, transmits the output control signal to the pixels connected to the post-stage output terminal Out-Put to drive the pixels to emit light. That is, the driving signal transmitted to the pixels is the output control signal. Moreover, it should be noted that the potential of the output control signal transmitted to the pixels connected to the post-stage output terminal Out-Put at this time is greater than or equal to the potential of the first power supply signal. Preferably, the potential of the transmitted output control signal is equal to the potential of the first power supply signal.

It should be noted that the potential threshold may be a predetermined value between the potential of the first power supply signal and the potential of the second power supply signal. Moreover, in some embodiments of the present disclosure, the fact that the potential of the pre-stage signal is less than the potential threshold may be configured to indicate that the potential of the pre-stage signal is close to the potential of the second power supply signal, and a difference value between the potential of the pre-stage signal and the potential of the first power supply signal is greater than a difference value threshold; the fact that the potential of the pre-stage signal is greater than the potential threshold may be configured to indicate that the potential of the pre-stage signal is close to the potential of the first power supply signal, and a difference value between the potential of the pre-stage signal and the potential of the first power supply signal is less than the difference value threshold. Under such a logic, once the potential of the pre-stage signal is greater than the potential threshold, that is, close to the potential of the first power supply signal, and the VX platform appears, then the potential of the signal transmitted to the post-stage output terminal Out-Put (that is, the driving signal finally transmitted to the pixels) may be directly controlled to be close to the potential of the first power supply signal through the post-stage control circuit 02, without synchronously transmitting the pre-stage signal which is output by the pre-stage output terminal Out and of which the potential is the intermediate potential VX to the post-stage output terminal Out-Put, thereby eliminating the VX platform and improving the problem of poor transverse striations. However, when the potential of the pre-stage signal is less than the potential threshold, that is, away from the potential of the first power supply signal, then the pre-stage signal from the pre-stage output terminal Out may be synchronized to the post-stage output terminal Out-Put through the post-stage control circuit 02, that is, the pre-stage signal is transmitted to the pixels as the driving signal.

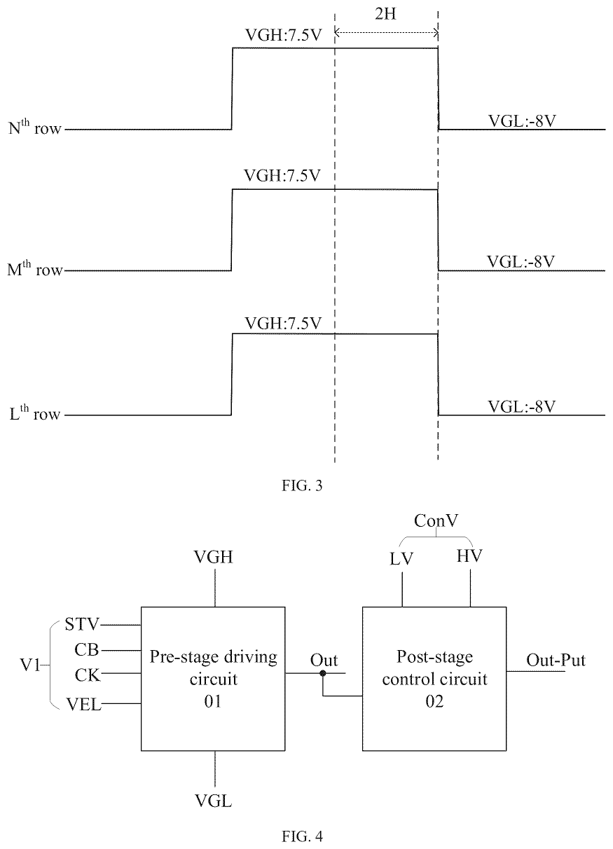

For example, for a scene where the potential of the first power supply signal is 7.5V and the potential of the second power supply signal is −8V, the potential threshold may be −5V. Based on this, by comparing the waveform diagrams shown in FIG. 2 and FIG. 3, it can be seen that once the potential of the pre-stage signal is higher than −5V (for example, equal to −4V, −2 or 0), that is, the potential of the pre-stage signal is close to the potential of the first power supply signal, that is, the VX platform shown in FIG. 2 appears, then the potential of the driving signal transmitted to the pixels through the post-stage output terminal Out-Put may be directly controlled to be equal to the potential of the first power supply signal through the post-stage control circuit 02, i.e., controlled to be 7.5V to eliminate the VX platform. On the contrary, when the potential of the pre-stage signal is less than −5V (for example, equal to −8V), that is, the potential of the pre-stage signal is close to the potential of the second power supply signal, then the pre-stage signal output by the pre-stage output terminal Out may be directly synchronized to the post-stage output terminal Out-Put through the post-stage control circuit 02, that is, the driving signal with the potential being equal to the potential of the pre-stage signal, for example, −8V, is transmitted to the pixels. In this example, even under the influence of high temperature reliability and process fluctuation, potential fluctuation of the driving signals transmitted to all rows of pixels can be controlled between 0 and −5V, which ensures output uniformity.

In summary, the embodiment of the present disclosure provides the shift register unit. The shift register unit includes the pre-stage driving circuit and the post-stage control circuit. The pre-stage driving circuit can control the connection between the first power supply terminal or the second power supply terminal and the pre-stage output terminal to be switched on and transmit the pre-stage signal to the pre-stage output terminal. The post-stage control circuit can control the pre-stage output terminal or a connection between the output control terminal and the post-stage output terminal to be switched on connected to the pixels based on the pre-stage signal and the output control signal provided by the output control terminal, and when a connection between the output control terminal and the post-stage output terminal is controlled to be switched on, the potential of the transmitted output control signal is greater than or equal to the potential of the first power supply signal provided by the first power supply terminal. In this way, when the potential of the pre-stage signal is close to the potential of the first power supply signal, but step abnormality of the intermediate potential occurs, the potential of the driving signal transmitted to the pixels is directly controlled to be close to the potential of the first power supply signal, so that the step abnormality is eliminated, better output stability is ensured, and a better display effect of the display panel is further ensured.

FIG. 4 is a schematic structural diagram of another shift register unit according to an embodiment of the present disclosure. As shown in FIG. 4, the output control terminal ConV described in the embodiment of the present disclosure may include a first output control terminal LV and a second output control terminal HV, and the potential of an output control signal provided by the second output control terminal HV is not less than the potential of the first power supply signal. Based on this, the post-stage control circuit 02 described in the embodiment of the present disclosure may be configured as:

Based on the pre-stage signal and an output control signal provided by the first output control terminal LV, the switching on and off of the connection between the pre-stage output terminal Out and the post-stage output terminal Out-Put is controlled. In addition, when the pre-stage output terminal Out is controlled to be decoupled from the post-stage output terminal OutPut, the second output control terminal HV is connected with the post-stage output terminal OutPut.

Exemplarily, if the potential of the pre-stage signal is less than the potential threshold, then the post-stage control circuit 02 may control the connection between the pre-stage output terminal Out and the post-stage output terminal Out-Put to be switched on based on the pre-stage signal with a smaller potential and the output control signal provided by the first output control terminal LV. On the basis of controlling the connection between pre-stage output terminal Out and the post-stage output terminal Out-Put to be switched on, the second output control terminal HV may be decoupled from the post-stage output terminal Out-Put. If the potential of the pre-stage signal is greater than the potential threshold, then the post-stage control circuit 02 may control the pre-stage output terminal Out to be decoupled from the post-stage output terminal Out-Put based on the pre-stage signal with a larger potential and the output control signal provided by the first output control terminal LV. On the basis of controlling the pre-stage output terminal Out to be decoupled from the post-stage output terminal Out-Put, the second output control terminal HV may be connected with the post-stage output terminal Out-Put.

It can also be seen that the potential of the output control signal provided by the first output control terminal LV should be greater than the potential of the second power supply signal and less than the potential of the output control signal provided by the second output control terminal HV. For example, assuming that the potential threshold is −5V, the potential of the first power supply signal is +8V, the potential of the second power supply signal is −8V, and the potential of the output control signal provided by the second output control terminal HV is equal to the potential of the first power supply signal, then the potential of the output control signal provided by the first output control terminal LV may be set to −3V, and the potential of the output control signal provided by the second output control terminal HV may be set to +8V. Of course, the potential of the output control signal provided by the first output control terminal LV may be positively correlated with the potential threshold. That is, the smaller the potential threshold, the smaller the potential of the output control signal provided by the first output control terminal LV may be set; on the contrary, the greater the potential threshold, the greater the potential of the output control signal provided by the first output control terminal LV may be set. In other words, the potential of the output control signal provided by the first output control terminal LV may be dynamically set and adjusted according to product characteristics.

Optionally, as described in the above embodiment, it can be known that the potential of the first power supply signal provided by the embodiment of the present disclosure is a high potential, and the potential of the second power supply signal is a low potential. Accordingly, the potential of the output control signal provided by the first output control terminal LV is a low potential. The output control signal provided by the second output control terminal HV is a high potential. Of course, in some other embodiments, a clock signal terminal may be disposed to replace the first output control terminal LV and the second output control terminal HV, and the clock signal terminal is disposed to flexibly provide a required clock signal as the output control signal based on the potential of the pre-stage signal.

Optionally, based on FIG. 4, FIG. 5 shows a schematic structural diagram of yet another shift register according to an embodiment of the present disclosure. As shown in FIG. 5, the post-stage control circuit 02 according to the embodiment of the present disclosure may include a switching sub-circuit 021 and an isolation sub-circuit 022.

The switching sub-circuit 021 may be respectively connected to the first output control terminal LV, the pre-stage output terminal Out and the post-stage output terminal Out-Put. The switching sub-circuit 021 may be configured to control the switching on and off of the connection between the pre-stage output terminal Out and the post-stage output terminal Out-Put based on the pre-stage signal and the output control signal provided by the first output control terminal LV.

The isolation sub-circuit 022 may be respectively connected to the second output control terminal HV and the post-stage output terminal Out-Put. The isolation sub-circuit 022 may be configured to isolate the second output control terminal HV and the post-stage output terminal Out-Put, and enable the second output control terminal HV and the post-stage output terminal Out-Put to be connected when the switching sub-circuit 021 controls the pre-stage output terminal OUT to be decoupled from the post-stage output terminal Out-Put.

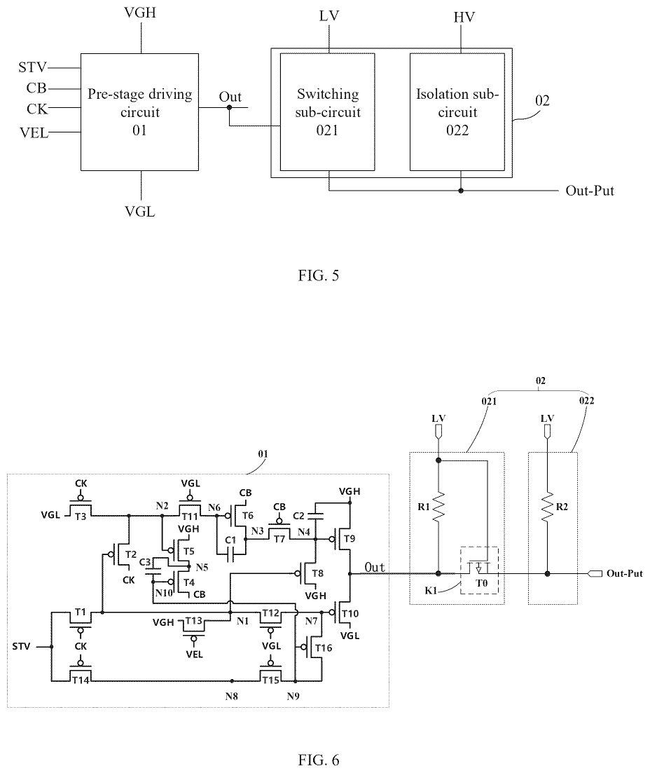

Optionally, based on FIG. 5, FIG. 6 shows a circuit structural diagram of a shift register unit according to an embodiment of the present disclosure. As shown in FIG. 6, the switching sub-circuit 021 may include a switch K1 and a first resistor R1. The isolation sub-circuit 022 may include a second resistor R2.

A control terminal of the switch K1 may be connected to the first output control terminal LV, an input terminal of the switch K1 may be connected to the pre-stage output terminal Out, and an output terminal of the switch K1 may be connected to the post-stage output terminal OutPut.

Exemplarily, still referring to FIG. 6, it can be seen that the switch K1 may include a switching transistor T0.

A gate electrode of the switching transistor T0 is connected to the first output control terminal LV as the control terminal of the switch K1, a first electrode of the switching transistor T0 is connected to the pre-stage output terminal Out as the input terminal of the switch K1, and a second electrode of the switching transistor T0 is connected to the post-stage output terminal Out-Put as the output terminal of the switch K1.

Of course, in some other embodiments, the switch K1 may also include a single-pole single-throw switch.

One terminal of the first resistor R1 may be connected to the pre-stage output terminal Out, and the other terminal of the first resistor R1 may be connected to the first output control terminal LV.

One terminal of the second resistor R2 may be connected to the second output control terminal HV, and the other terminal of the second resistor R2 may be connected to the post-stage output terminal Out-Put.

Optionally, with continued reference to FIG. 4 and FIG. 5, it can also be seen that the driving control terminal V1 may include a first clock terminal CK, a second clock terminal CB, a start signal terminal STV and a potential control terminal VEL.

The pre-stage driving circuit 01 may be configured to control the switching on and off of the connection between the first power supply terminal VGH and the pre-stage output terminal Out and the switching on and off of the connection between the second power supply terminal VGL and the pre-stage output terminal Out based on a first clock signal provided by the first clock terminal CK, a second clock signal provided by the second clock terminal CB, a start signal provided by the start signal terminal STV, a potential control signal provided by the potential control terminal VEL, the first power supply signal and the second power supply signal provided by the second power supply terminal VGL.

Optionally, with continued reference to FIG. 6, it can be seen that the pre-stage driving circuit 01 may include a first transistor T1, a second transistor T2, a third transistor T3, a fourth transistor T4, a fifth transistor T5, a sixth transistor T6, a seventh transistor T7, an eighth transistor T8, a ninth transistor T9, a tenth transistor T10, an eleventh transistor T11, a twelfth transistor T12, a thirteenth transistor T13, a fourteenth transistor T14 a fifteenth transistor T15, a sixteenth transistor T16, a first capacitor C1, a second capacitor C2 and a third capacitor C3.

A gate electrode of the first transistor T1 may be connected to the first clock terminal CK, a first electrode of the first transistor T1 may be connected to the start signal terminal STV, a second electrode of the first transistor T1 may be connected to a first node N1.

A gate electrode of the second transistor T2 may be connected to the first node N1, a first electrode of the second transistor T2 may be connected to the first clock terminal CK, and the first electrode of the second transistor T2 may be connected to a second node N2.

A gate electrode of the third transistor T3 may be connected to the first clock terminal CK, a first electrode of the third transistor T3 may be connected to the second power supply terminal VGL, and a second electrode of the third transistor T3 may be connected to the second node N2.

A gate electrode of the fourth transistor T4 may be connected to a tenth node N10, a first electrode of the fourth transistor T4 may be connected to the second clock terminal CB, and a second electrode of the third transistor T3 may be connected to a fifth node N5.

A gate electrode of the fifth transistor T5 may be connected to the second node N2, a first electrode of the fifth transistor T5 may be connected to the first power supply terminal VGH, and a second electrode of the fifth transistor T5 may be connected to the fifth node N5.

A gate electrode of the sixth transistor T6 may be connected to a sixth node N6, a first electrode of the sixth transistor T6 may be connected to the second clock terminal CB, and a second electrode of the sixth transistor T6 may be connected to a third node N3.

A gate electrode of the seventh transistor T7 may be connected to the second clock terminal CB, a first electrode of the seventh transistor T7 may be connected to the third node N3, and a second electrode of the seventh transistor T7 may be connected to a fourth node N4.

A gate electrode of the eighth transistor T8 may be connected to the first node N1, a first electrode of the eighth transistor T8 may be connected to the first power supply terminal VGH, and a second electrode of the eighth transistor T8 may be connected to the fourth node N4.

A gate electrode of the ninth transistor T9 may be connected to the fourth node N4, a first electrode of the ninth transistor T9 may be connected to the first power supply terminal VGH, and a second electrode of the ninth transistor T9 may be connected to the pre-stage output terminal Out.

A gate electrode of the tenth transistor T10 may be connected to a seventh node N7, a first electrode of the tenth transistor T10 may be connected to the second power supply terminal VGL, and a second electrode of the tenth transistor T10 may be connected to the pre-stage output terminal Out.

A gate electrode of the eleventh transistor T11 may be connected to the second power supply terminal VGL, a first electrode of the eleventh transistor T11 may be connected to the second node N2, and a second electrode of the eleventh transistor T11 may be connected to the sixth node N6.

A gate electrode of the twelfth transistor T12 may be connected to the second power supply terminal VGL, a first electrode of the twelfth transistor T12 may be connected to the first node N1, and a second electrode of the twelfth transistor T12 may be connected to the seventh node N7.

A gate electrode of the thirteenth transistor T13 may be connected to the potential control terminal VEL, a first electrode of the thirteenth transistor T13 may be connected to the first power supply terminal VGH, and a second electrode of the thirteenth transistor T13 may be connected to the first node N1.

A gate electrode of the fourteenth transistor T14 may be connected to the first clock terminal CK, a first electrode of the fourteenth transistor T14 may be connected to the start signal terminal STV, and a second electrode of the fourteenth transistor T14 may be connected to an eighth node N8.

A gate electrode of the fifteenth transistor T15 may be connected to the second power supply terminal VGL, a first electrode of the fifteenth transistor T15 may be connected to the eighth node N8, and a second electrode of the fifteenth transistor T15 may be connected to a ninth node N9.

A gate electrode and a first electrode of the sixteenth transistor T16 may both be connected to the ninth node N9, and a second electrode of the sixteenth transistor T16 may be connected to the seventh node N7.

One terminal of the first capacitor C1 may be connected to the sixth node N6, and the other terminal of the first capacitor C1 may be connected to the third node N3. One terminal of the second capacitor C2 may be connected to the fourth node N4, and the other terminal of the second capacitor C2 may be connected to the first power supply terminal VGH. One terminal of the third capacitor C3 may be connected to the fifth node N5, and the other terminal of the third capacitor C3 may be connected to the ninth node N9.

Optionally, with continued reference to FIG. 6, it can be seen that the transistors in the pre-stage driving circuit 01 may all be P-type transistors, and a material of the P-type transistor may include the LTPS. In addition, the switching transistor T0 included in the post-stage control circuit 02 may also be the P-type transistor made of the LTPS material.

It should be noted that the pre-stage driving circuit 01 in the shift register unit shown in FIG. 6 may be considered as a circuit of a 16T3C structure. In some other embodiments, the pre-stage driving circuit 01 may also be a circuit of other structures, such as 17T2C, which is not limited by the embodiment of the present disclosure.

Based on the structure shown in FIG. 6, by taking the potential of the first power supply signal as +7.5V, and setting the potential of the first output control signal provided by the first output control terminal LV as −3V, and the potential of the second output control signal provided by the second output control terminal HV to be equal to the potential of the first power supply signal, i.e., +7.5V, and assuming that a threshold voltage Vth of the switching transistor T0 is −2V as an example, the working principle of the post-stage control circuit 02 is described as follows:

When the potential of the pre-stage signal transmitted from the pre-stage driving circuit 01 to the pre-stage output terminal Out is less than −5V, the switching transistor T0 may be turned on, and then the pre-stage output terminal Out may be connected with the post-stage output terminal Out-Put. At this time, the pre-stage signal of which the potential is less than −5V may be synchronously transmitted to the post-stage output terminal Out-Put through the turned-on switching transistor T0, so that the post-stage output terminal Out-Put outputs to a low voltage. That is, the potential of the driving signal transmitted to the pixels through the post-stage output terminal Out-Put is enabled to be a low potential.

When the potential of the pre-stage signal transmitted from the pre-stage driving circuit 01 to the pre-stage output terminal Out is greater than −5V, the switching transistor T0 may be turned off, and then the pre-stage output terminal Out may be decoupled from the post-stage output terminal Out-Put. At this time, the second output control terminal HV may transmit the output control signal with a potential of +7.5V to the post-stage output terminal Out-Put, so that the post-stage output terminal Out-Put outputs to a high voltage. That is, the potential of the driving signal transmitted to the pixels through the post-stage output terminal Out-Put is enabled to be a high potential and equal to the potential of the first power supply signal.

Thus, it can also be known that the potential threshold in the above setting scene may be −5V. Based on this logic, by comparing FIG. 2 and FIG. 3, it can be seen that the VX platforms can be eliminated, so that the potential difference value of the driving signals transmitted to all rows of pixels is smaller or even no difference exists, and the potentials can be unified as much as possible, thus ensuring a better display effect.

In summary, the embodiment of the present disclosure provides the shift register unit. The shift register unit includes the pre-stage driving circuit and the post-stage control circuit. The pre-stage driving circuit can control the connection between the first power supply terminal or the second power supply terminal and the pre-stage output terminal to be switched on and transmit the pre-stage signal to the pre-stage output terminal. The post-stage control circuit can control the pre-stage output terminal or a connection between the output control terminal and the post-stage output terminal to be switched on connected to the pixels based on the pre-stage signal and the output control signal provided by the output control terminal, and when a connection between the output control terminal and the post-stage output terminal is controlled to be switched on, the potential of the transmitted output control signal is greater than or equal to the potential of the first power supply signal provided by the first power supply terminal. In this way, when the potential of the pre-stage signal is close to the potential of the first power supply signal, but step abnormality of the intermediate potential occurs, the potential of the driving signal transmitted to the pixels is directly controlled to be close to the potential of the first power supply signal, so that the step abnormality is eliminated, better output stability is ensured, and a better display effect of the display panel is further ensured.

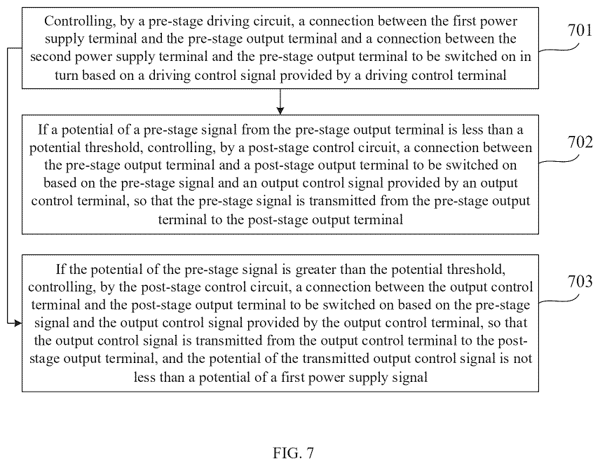

FIG. 7 is a flowchart of a driving method of a shift register unit according to an embodiment of the present disclosure. This method is applied to the shift register unit as described in the above embodiments of the present disclosure. As shown in FIG. 7, the method includes:
in step 701: controlling, by the pre-stage driving circuit, a connection between the first power supply terminal and the pre-stage output terminal and a connection between the second power supply terminal and the pre-stage output terminal to be switched on in turn based on the driving control signal provided by the driving control terminal;
in step 702: if a potential of the pre-stage signal from the pre-stage output terminal is less than a potential threshold, controlling, by the post-stage control circuit, a connection between the pre-stage output terminal and the post-stage output terminal to be switched on based on the pre-stage signal and the output control signal provided by the output control terminal, so that the pre-stage signal is transmitted from the pre-stage output terminal to the post-stage output terminal; and
in step 703: if the potential of the pre-stage signal is greater than the potential threshold, controlling, by the post-stage control circuit, a connection between the output control terminal and the post-stage output terminal to be switched on based on the pre-stage signal and the output control signal provided by the output control terminal, so that the output control signal is transmitted from the output control terminal to the post-stage output terminal, and the potential of the transmitted output control signal is not less than the potential of the first power supply signal;
wherein the potential threshold is between the potential of the first power supply signal and the potential of the second power supply signal provided by the second power supply terminal.

Optionally, the pre-stage driving circuit may control the switch-on duration of the connection between the first power supply terminal and the pre-stage output terminal to be less than the switch-on duration of the connection between the second power supply terminal and the pre-stage output terminal.

Optionally, referring to FIG. 4 to FIG. 6, it can be seen that the output control terminal ConV may include the first output control terminal LV and the second output control terminal HV, and the potential of the output control signal provided by the second output control terminal HV is not less than the potential of the first power supply signal. Based on this,
the post-stage control circuit controls a connection between the pre-stage output terminal and the post-stage output terminal to be switched on based on the pre-stage signal and the output control signal provided by the output control terminal, that is, the above step 702 may include: controlling, by the post-stage control circuit, a connection between the pre-stage output terminal and the post-stage output terminal to be switched on based on the pre-stage signal and the output control signal provided by the first output control terminal.

The post-stage control circuit controls a connection between the output control terminal and the post-stage output terminal to be switched on based on the pre-stage signal and the output control signal provided by the output control terminal, that is, the above step 703 may include:
controlling, by the post-stage control circuit, the pre-stage output terminal to be decoupled from the post-stage output terminal based on the pre-stage signal and the output control signal provided by the first output control terminal, so that the second output control terminal is connected with the post-stage output terminal.

Optionally, in some embodiments, the potential of the output control signal provided by the first output control terminal may be positively correlated with the potential threshold.

Since the driving method of a shift register unit may have basically the same embodiments and technical effects as the shift register unit described in the preceding embodiments, for the sake of brevity, the descriptions will not be repeated here.

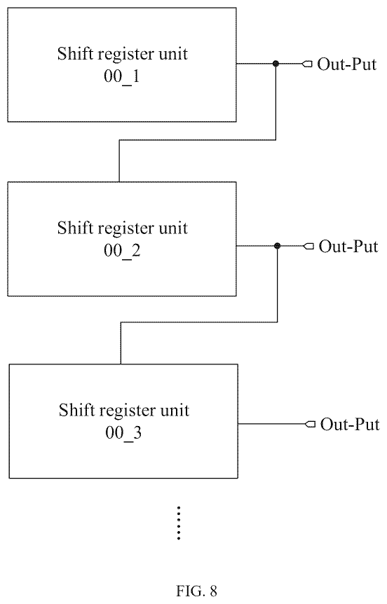

FIG. 8 is a schematic structural diagram of a gate driving circuit according to an embodiment of the present disclosure. As shown in FIG. 8, the gate driving circuit includes at least two cascaded shift register units 00 as described in the above embodiments of the present disclosure. For example, FIG. 8 shows three cascaded shift register units 00_1, 00_2 and 00_3.

The post-stage output terminal Out-Put of each stage of shift register unit 00 may be cascaded with the next stage of shift register unit 00, and may be connected to the pixels in the display panel to transmit gate driving signals to the pixels, thereby driving the pixels to emit light. Here, the shift register unit 00 included in the gate driving circuit may be connected to the pixels through a gate line Gate to instruct a data signal line to transmit a data signal to the pixels.

Of course, in some other embodiments, other display driving circuits other than the gate driving circuit may also include the shift register unit 00 as described in the above embodiments of the present disclosure, so as to ensure better output stability, thereby better improving the display effect of the display panel. For example, in a light-emitting driving circuit, the pixels are coupled through light-emitting control lines EM to instruct driving power supply lines VDD to transmit driving power supply signals to the pixels. That is, the light-emitting driving circuit may also be a GOA circuit integrated in the substrate, including a plurality of cascaded GOA units. Alternatively, in a reset driving circuit, the pixels are coupled through reset lines Reset to instruct reset power supply lines Vinit to transmit reset power supply signals to the pixels. That is, the reset driving circuit may also be a GOA circuit integrated in the substrate, including a plurality of cascaded GOA units. The examples here are only schematically illustrated.

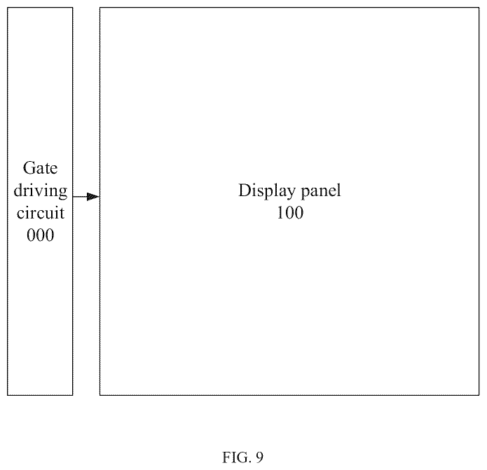

FIG. 9 is a structural schematic diagram of a display apparatus according to an embodiment of the present disclosure. As shown in FIG. 9, the display apparatus includes a display panel 100 and the gate driving circuit 000 as shown in FIG. 8.

The display panel 100 includes a plurality of pixels (not shown in the figure), and the gate driving circuit 000 is connected to the plurality of pixels and configured to transmit gate driving signals to the plurality of pixels to drive the plurality of pixels to emit light.

Optionally, transistors in the pixels may be N-type transistors, and a material of the N-type transistor may include an oxide material. In this way, with the GOA circuit of the LTPS described in the above embodiment, the display apparatus may be an LTPO architecture setting.

As described in the above embodiment, the gate driving circuit 000 may be connected to the plurality of rows of pixels in one-to-one correspondence through a plurality of gate lines. In addition, in some other embodiments, the display apparatus may further include the light-emitting driving circuit and the reset driving circuit. The light-emitting driving circuit and the reset driving circuit also each include the shift register units as described in the above embodiments, which are connected to the plurality of rows of pixels in one-to-one correspondence to drive the pixels to emit light.

Optionally, the display apparatus described in the embodiment of the present disclosure may be any product or component with a display function, such as an OLED display apparatus and an active-matrix organic light-emitting diode (AMOLED) display apparatus.

The AMOLED display apparatus has the advantages of small power consumption, wide working temperature range, low cost, high contrast, wide viewing angle, wide color gamut and thinner display panel, can realize flexible display and gradually becomes the “crown” of the next generation display. The OLED display apparatus can meet most requirements of high performance and large capacity of a display device in current information times, can be configured for indoor and outdoor lighting, can serve as wallpaper decorations and made into folded electronic newspapers, and can also be applied to portable electronic products such as mobile phones, tablet computers and wearable electronic devices.

It should be noted that the terms used in the embodiments of the present disclosure are only configured to explain the embodiments, and are not intended to limit the present disclosure. Unless otherwise defined, the technical terms or scientific terms used in the embodiments of the present disclosure shall be taken to mean the ordinary meanings as understood by the ordinary skill in the art to which the present disclosure belongs.

For example, “first”, “second” or “third” and similar words used in the description and claims of patent application of the present disclosure do not denote any order, quantity, or importance, but are merely configured to distinguish different constituents. “Connected” or “coupled” refers to electrically connected. Similarly, “a” or “one” and similar words are not intended to limit the number, but to denote the number of at least one. “Includes” or “contains” and similar words are intended to mean that the elements or objects before the “includes” or “contains” cover the elements or objects and equivalents thereof listed after the “includes” or “contains”, without excluding other elements or objects. “Upper”, “lower”, “left” or “right” and the like are merely configured to indicate a relative positional relationship, and when the absolute position of a described object changes, the relative positional relationship may also change accordingly.

The foregoing descriptions are merely optional embodiments of the present disclosure, and are not intended to limit the present disclosure. Within the spirit and principles of the present disclosure, any modifications, equivalent substitutions, improvements, etc., are within the protection scope of the present disclosure.

1. A shift register unit, comprising:
a pre-stage driving circuit respectively connected to a driving control terminal, a first power supply terminal, a second power supply terminal and a pre-stage output terminal, and configured to control switching on and off of a connection between the first power supply terminal and the pre-stage output terminal and switching on and off of a connection between the second power supply terminal and the pre-stage output terminal based on a driving control signal provided by the driving control terminal; and
a post-stage control circuit respectively connected to the pre-stage output terminal, an output control terminal and a post-stage output terminal, wherein the post-stage output terminal is configured to be connected to pixels in a display panel, and the post-stage control circuit is configured to: control a connection between a first terminal and the post-stage output terminal to be switched on based on a pre-stage signal from the pre-stage output terminal and an output control signal provided by the output control terminal, so that the pre-stage signal is transmitted from the first terminal to the post-stage output terminal, the terminal is one of the pre-stage output terminal and the output control terminal, and a potential of the transmitted output control signal is not less than a potential of a first power supply signal provided by the first power supply terminal.

2. The shift register unit according to claim 1, wherein a switch-on duration of the connection between the first power supply terminal and the pre-stage output terminal is less than a switch-on duration of the connection between the second power supply terminal and the pre-stage output terminal; the output control terminal comprises a first output control terminal and a second output control terminal, wherein a potential of an output control signal provided by the second output control terminal is not less than the potential of the first power supply signal; and
the post-stage control circuit is configured to control switching on and off of a connection between the pre-stage output terminal and the post-stage output terminal based on the pre-stage signal and an output control signal provided by the first output control terminal, and control a connection between the second output control terminal and the post-stage output terminal to be switched on upon controlling the connection between the pre-stage output terminal and the post-stage output terminal to be switched off.

3. The shift register unit according to claim 2, wherein the post-stage control circuit comprises:
a switching sub-circuit respectively connected to the first output control terminal, the pre-stage output terminal and the post-stage output terminal, and configured to control the switching on and off of the connection between the pre-stage output terminal and the post-stage output terminal based on the pre-stage signal and the output control signal provided by the first output control terminal; and
an isolation sub-circuit respectively connected to the second output control terminal and the post-stage output terminal, and configured to isolate the second output control terminal from the post-stage output terminal, and control a connection between the second output control terminal and the post-stage output terminal to be switched on when the switching sub-circuit controls the connection between the pre-stage output terminal and the post-stage output terminal to be switched off.

4. The shift register unit according to claim 3, wherein the switching sub-circuit comprises a switch and a first resistor;
a control terminal of the switch is connected to the first output control terminal, an input terminal of the switch is connected to the pre-stage output terminal, and an output terminal of the switch is connected to the post-stage output terminal; and
one terminal of the first resistor is connected to the pre-stage output terminal, and the other terminal of the first resistor is connected to the first output control terminal.

5. The shift register unit according to claim 4, wherein the switch comprises: a switching transistor;
wherein a gate electrode of the switching transistor is connected to the first output control terminal as the control terminal of the switch, a first electrode of the switching transistor is connected to the pre-stage output terminal as the input terminal of the switch, and a second electrode of the switching transistor is connected to the post-stage output terminal as the output terminal of the switch.

6. The shift register unit according to claim 3, wherein the isolation sub-circuit comprises: a second resistor; and
one terminal of the second resistor is connected to the second output control terminal, and the other terminal of the second resistor is connected to the post-stage output terminal.

7. The shift register unit according to claim 1, wherein the driving control terminal comprises a first clock terminal, a second clock terminal, a start signal terminal and a potential control terminal;
the pre-stage driving circuit is configured to control the switching on and off of the connection between the first power supply terminal and the pre-stage output terminal and the switching on and off of the connection between the second power supply terminal and the pre-stage output terminal based on a first clock signal provided by the first clock terminal, a second clock signal provided by the second clock terminal, a start signal provided by the start signal terminal, a potential control signal provided by the potential control terminal, the first power supply signal and a second power supply signal provided by the second power supply terminal.

8. The shift register unit according to claim 7, wherein the pre-stage driving circuit comprises a first transistor, a second transistor, a third transistor, a fourth transistor, a fifth transistor, a sixth transistor, a seventh transistor, an eighth transistor, a ninth transistor, a tenth transistor, an eleventh transistor, a twelfth transistor, a thirteenth transistor, a fourteenth transistor, a fifteenth transistor, a sixteenth transistor, a first capacitor, a second capacitor and a third capacitor;
wherein a gate electrode of the first transistor is connected to the first clock terminal, a first electrode of the first transistor is connected to the start signal terminal, and a second electrode of the first transistor is connected to a first node;
a gate electrode of the second transistor is connected to the first node, a first electrode of the second transistor is connected to the first clock terminal, and the first electrode of the second transistor is connected to a second node;
a gate electrode of the third transistor is connected to the first clock terminal, a first electrode of the third transistor is connected to the second power supply terminal, and a second electrode of the third transistor is connected to the second node;
a gate electrode of the fourth transistor is connected to a tenth node, a first electrode of the fourth transistor is connected to the second clock terminal, and a second electrode of the third transistor is connected to a fifth node;
a gate electrode of the fifth transistor is connected to the second node, a first electrode of the fifth transistor is connected to the first power supply terminal, and a second electrode of the fifth transistor is connected to the fifth node;
a gate electrode of the sixth transistor is connected to a sixth node, a first electrode of the sixth transistor is connected to the second clock terminal, and a second electrode of the sixth transistor is connected to a third node;
a gate electrode of the seventh transistor is connected to the second clock terminal, a first electrode of the seventh transistor is connected to the third node, and a second electrode of the seventh transistor is connected to a fourth node;
a gate electrode of the eighth transistor is connected to the first node, a first electrode of the eighth transistor is connected to the first power supply terminal, and a second electrode of the eighth transistor is connected to the fourth node;
a gate electrode of the ninth transistor is connected to the fourth node, a first electrode of the ninth transistor is connected to the first power supply terminal, and a second electrode of the ninth transistor is connected to the pre-stage output terminal;
a gate electrode of the tenth transistor is connected to a seventh node, a first electrode of the tenth transistor is connected to the second power supply terminal, and a second electrode of the tenth transistor is connected to the pre-stage output terminal;
a gate electrode of the eleventh transistor is connected to the second power supply terminal, a first electrode of the eleventh transistor is connected to the second node, and a second electrode of the eleventh transistor is connected to the sixth node;
a gate electrode of the twelfth transistor is connected to the second power supply terminal, a first electrode of the twelfth transistor is connected to the first node, and a second electrode of the twelfth transistor is connected to the seventh node;
a gate electrode of the thirteenth transistor is connected to the potential control terminal, a first electrode of the thirteenth transistor is connected to the first power supply terminal, and a second electrode of the thirteenth transistor is connected to the first node;
a gate electrode of the fourteenth transistor is connected to the first clock terminal, a first electrode of the fourteenth transistor is connected to the start signal terminal, and a second electrode of the fourteenth transistor is connected to an eighth node;
a gate electrode of the fifteenth transistor is connected to the second power supply terminal, a first electrode of the fifteenth transistor is connected to the eighth node, and a second electrode of the fifteenth transistor is connected to a ninth node;
a gate electrode and a first electrode of the sixteenth transistor are both connected to the ninth node, and a second electrode of the sixteenth transistor is connected to the seventh node; and
one terminal of the first capacitor is connected to the sixth node, and the other terminal of the first capacitor is connected to the third node; one terminal of the second capacitor is connected to the fourth node, and the other terminal of the second capacitor is connected to the first power supply terminal; and one terminal of the third capacitor is connected to the fifth node, and the other terminal of the third capacitor is connected to the ninth node.

9. The shift register unit according to claim 1, wherein transistors in the pre-stage driving circuit are P-type transistors, and a material of the P-type transistor comprises low temperature poly-silicon;
wherein the potential of the first power supply signal provided by the first power supply terminal is greater than a potential of a second power supply signal provided by the second power supply terminal.

10. A driving method of a shift register unit, applied to the shift register unit according to claim 1, wherein the method comprises:
controlling, by the pre-stage driving circuit, a connection between the first power supply terminal and the pre-stage output terminal and a connection between the second power supply terminal and the pre-stage output terminal to be switched on in turn based on the driving control signal provided by the driving control terminal;
if a potential of the pre-stage signal from the pre-stage output terminal is less than a potential threshold, controlling, by the post-stage control circuit, a connection between the pre-stage output terminal and the post-stage output terminal to be switched on based on the pre-stage signal and the output control signal provided by the output control terminal, so that the pre-stage signal is transmitted from the pre-stage output terminal to the post-stage output terminal; and
if the potential of the pre-stage signal is greater than the potential threshold, controlling, by the post-stage control circuit, a connection between the output control terminal and the post-stage output terminal to be switched on based on the pre-stage signal and the output control signal provided by the output control terminal, so that the output control signal is transmitted from the output control terminal to the post-stage output terminal, and the potential of the transmitted output control signal is not less than the potential of the first power supply signal;
wherein the potential threshold is between the potential of the first power supply signal and a potential of a second power supply signal provided by the second power supply terminal.

11. The method according to claim 10, wherein the pre-stage driving circuit controls a switch-on duration of the connection between the first power supply terminal and the pre-stage output terminal to be less than a switch-on duration of the connection between the second power supply terminal and the pre-stage output terminal;
the output control terminal comprises the first output control terminal and the second output control terminal, wherein a potential of the output control signal provided by the second output control terminal is not less than the potential of the first power supply signal;
controlling, by the post-stage control circuit, a connection between the pre-stage output terminal and the post-stage output terminal to be switched on based on the pre-stage signal and the output control signal provided by the output control terminal comprises:
controlling, by the post-stage control circuit, a connection between the pre-stage output terminal and the post-stage output terminal to be switched on based on the pre-stage signal and the output control signal provided by the first output control terminal;
and, controlling, by the post-stage control circuit, a connection between the output control terminal and the post-stage output terminal to be switched on based on the pre-stage signal and the output control signal provided by the output control terminal comprises:
controlling, by the post-stage control circuit, the connection between the pre-stage output terminal and the post-stage output terminal to be switched off based on the pre-stage signal and the output control signal provided by the first output control terminal, so that a connection between the second output control terminal and the post-stage output terminal is switched on.

12. The method according to claim 11, wherein a potential of the output control signal provided by the first output control terminal is positively correlated to the potential threshold.

13. A gate driving circuit comprising at least two cascaded shift register units, wherein each of the shift register units comprises:
a pre-stage driving circuit respectively connected to a driving control terminal, a first power supply terminal, a second power supply terminal and a pre-stage output terminal, and configured to control switching on and off of a connection between the first power supply terminal and the pre-stage output terminal and switching on and off of a connection between the second power supply terminal and the pre-stage output terminal based on a driving control signal provided by the driving control terminal; and
a post-stage control circuit respectively connected to the pre-stage output terminal, an output control terminal and a post-stage output terminal, wherein the post-stage output terminal is configured to be connected to pixels in a display panel, and the post-stage control circuit is configured to: control a connection between a first terminal and the post-stage output terminal to be switched on based on a pre-stage signal from the pre-stage output terminal and an output control signal provided by the output control terminal, so that the pre-stage signal is transmitted from the first terminal to the post-stage output terminal, the terminal is one of the pre-stage output terminal and the output control terminal, and a potential of the transmitted output control signal is not less than a potential of a first power supply signal provided by the first power supply terminal.

14. A display apparatus comprising: a display panel, and a gate driving circuit comprising at least two cascaded shift register units; wherein each of the shift register units comprises:
a pre-stage driving circuit respectively connected to a driving control terminal, a first power supply terminal, a second power supply terminal and a pre-stage output terminal, and configured to control switching on and off of a connection between the first power supply terminal and the pre-stage output terminal and switching on and off of a connection between the second power supply terminal and the pre-stage output terminal based on a driving control signal provided by the driving control terminal; and
a post-stage control circuit respectively connected to the pre-stage output terminal, an output control terminal and a post-stage output terminal, wherein the post-stage output terminal is configured to be connected to pixels in a display panel, and the post-stage control circuit is configured to: control a connection between a first terminal and the post-stage output terminal to be switched on based on a pre-stage signal from the pre-stage output terminal and an output control signal provided by the output control terminal, so that the pre-stage signal is transmitted from the first terminal to the post-stage output terminal, the terminal is one of the pre-stage output terminal and the output control terminal, and a potential of the transmitted output control signal is not less than a potential of a first power supply signal provided by the first power supply terminal;
wherein the display panel comprises a plurality of pixels, and the gate driving circuit is connected to the plurality of pixels and configured to transmit gate driving signals to the plurality of pixels to drive the plurality of pixels to emit light.

15. The display apparatus according to claim 14, wherein transistors in the pixels are N-type transistors, and a material of the N-type transistor comprises an oxide material.

16. The display apparatus according to claim 14, wherein a switch-on duration of the connection between the first power supply terminal and the pre-stage output terminal is less than a switch-on duration of the connection between the second power supply terminal and the pre-stage output terminal; the output control terminal comprises a first output control terminal and a second output control terminal, wherein a potential of an output control signal provided by the second output control terminal is not less than the potential of the first power supply signal; and
the post-stage control circuit is configured to control switching on and off of a connection between the pre-stage output terminal and the post-stage output terminal based on the pre-stage signal and an output control signal provided by the first output control terminal, and control a connection between the second output control terminal and the post-stage output terminal to be switched on upon controlling the connection between the pre-stage output terminal and the post-stage output terminal to be switched off.

17. The display apparatus according to claim 16, wherein the post-stage control circuit comprises:
a switching sub-circuit respectively connected to the first output control terminal, the pre-stage output terminal and the post-stage output terminal, and configured to control the switching on and off of the connection between the pre-stage output terminal and the post-stage output terminal based on the pre-stage signal and the output control signal provided by the first output control terminal; and
an isolation sub-circuit respectively connected to the second output control terminal and the post-stage output terminal, and configured to isolate the second output control terminal from the post-stage output terminal, and control a connection between the second output control terminal and the post-stage output terminal to be switched on when the switching sub-circuit controls the connection between the pre-stage output terminal and the post-stage output terminal to be switched off.

18. The display apparatus according to claim 17, wherein the switching sub-circuit comprises a switch and a first resistor;
a control terminal of the switch is connected to the first output control terminal, an input terminal of the switch is connected to the pre-stage output terminal, and an output terminal of the switch is connected to the post-stage output terminal; and
one terminal of the first resistor is connected to the pre-stage output terminal, and the other terminal of the first resistor is connected to the first output control terminal.

19. The display apparatus according to claim 18, wherein the switch comprises: a switching transistor;
wherein a gate electrode of the switching transistor is connected to the first output control terminal as the control terminal of the switch, a first electrode of the switching transistor is connected to the pre-stage output terminal as the input terminal of the switch, and a second electrode of the switching transistor is connected to the post-stage output terminal as the output terminal of the switch.

20. The display apparatus according to claim 17, wherein the isolation sub-circuit comprises: a second resistor; and
one terminal of the second resistor is connected to the second output control terminal, and the other terminal of the second resistor is connected to the post-stage output terminal.
